(19) United States
(12) Patent Application Publication
(10) Pub. No.: US 2026/0164707 A1
(43) Pub. Date: Jun. 11, 2026

(54) SEMICONDUCTOR DEVICE

(71) Applicant: Murata Manufacturing Co., Ltd., Kyoto-fu (JP)

(72) Inventors: Mari SAJI, Nagaokakyo-shi (JP); Akira FUJIHARA, Nagaokakyo-shi (JP)

(73) Assignee: Murata Manufacturing Co., Ltd., Kyoto-fu (JP)

(21) Appl. No.: 19/407,138

(22) Filed: Dec. 3, 2025

(30) Foreign Application Priority Data
Dec. 10, 2024 (JP) 2024-216001

(51) Int. Cl. H10D 30/65; H10D 64/27; H10W 74/10; H10W 74/43

(52) U.S. Cl. CPC H10D 30/657; H10D 64/518; H10W 74/137; H10W 74/147; H10W 74/43

(57) ABSTRACT

A semiconductor device includes a semiconductor substrate; a source region and a drain region located on an upper surface side of the semiconductor substrate so as to be spaced from each other; a body region located between the source region and the drain region; a drift region located between the body region and the drain region; a gate insulating film provided on the body region; a gate electrode provided on the gate insulating film; an insulating film provided on the drift region; a silicon oxynitride film provided on the insulating film; and a silicon nitride film provided on the silicon oxynitride film.

### CROSS-REFERENCE TO RELATED APPLICATION

This application claims benefit of priority to Japanese Patent Application No. 2024-216001, filed Dec. 10, 2024, the entire content of which is incorporated herein by reference.

### BACKGROUND

### Technical Field

The present disclosure relates to semiconductor devices.

### Background Art

U.S. Patent Application Publication No. 2018/0151726 discloses a semiconductor device including a source region, a drain region, and a body region located between the source region and the drain region. A drift region having a concentration of impurities lower than that of the drain region is provided between the drain region and the body region. An insulating film composed of silicon oxide (which is described as a silicide blocker in U.S. Patent Application Publication No. 2018/0151726) is further provided on the drift region.

### SUMMARY

In such a semiconductor device, a silicon nitride (SiN) film for exerting stress on the body region is provided in some cases. The structure including SiO₂ and SiN laminated over the drift region can result in degradation in the characteristics of the semiconductor device.

Accordingly, the present disclosure provides a semiconductor device with reduced degradation in characteristics.

A semiconductor device according to an aspect includes a semiconductor substrate; a source region and a drain region located on an upper surface side of the semiconductor substrate so as to be spaced from each other; a body region located between the source region and the drain region; a drift region located between the body region and the drain region; a gate insulating film provided on the body region; a gate electrode provided on the gate insulating film; an insulating film provided on the drift region; a silicon oxynitride film provided on the insulating film; and a silicon nitride film provided on the silicon oxynitride film.

The semiconductor device of the present disclosure has reduced degradation in characteristics.

### BRIEF DESCRIPTION OF THE DRAWINGS

FIG. 1 is a plan view of a semiconductor device according to a first embodiment;

FIG. 2 is a cross-sectional view taken along line II-II in FIG. 1;

FIG. 3 is an explanatory diagram for explaining the energy band of a lamination structure including a drain region, an insulating film, an SiON film, and an SiN film in the semiconductor device according to the first embodiment;

FIG. 4 is an explanatory diagram for explaining the energy band of a lamination structure of a drain region, an insulating film, an SiN film, and an SiO₂ film in an semiconductor device according to a comparative example;

FIG. 5 is a plan view of a semiconductor device according to a second embodiment;

FIG. 6 is a cross-sectional view taken along line VI-VI in FIG. 5;

FIG. 7 is a plan view of a semiconductor device according to a third embodiment; and

FIG. 8 is a cross-sectional view taken along line VIII-VIII in FIG. 7.

### DETAILED DESCRIPTION

Hereinafter, embodiments of the present disclosure will be described in detail with reference to the drawings. These embodiment are not intended to limit the present disclosure. Each embodiment described in the present disclosure is for illustrating an example; hence, configurations can be partially replaced or combined between different embodiments. For modification examples and a second and subsequent embodiments, description of the items common to those of a first embodiment will be omitted, and only different points will be described. In particular, the same or similar operational advantages by the same or similar configurations will not be referred to in each embodiment.

### First Embodiment

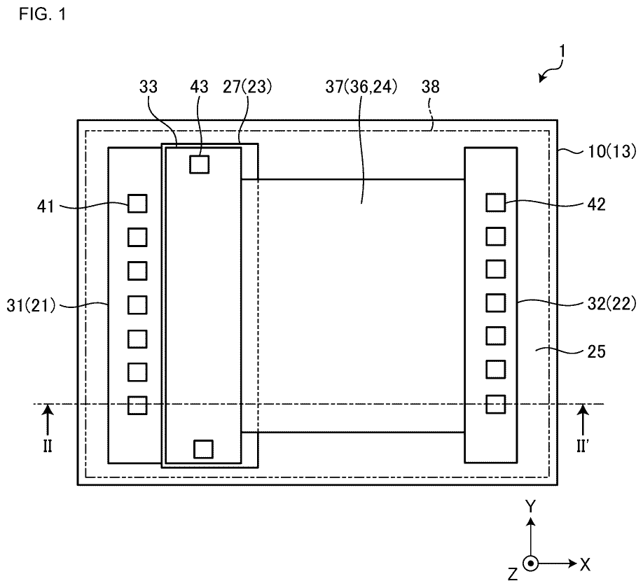

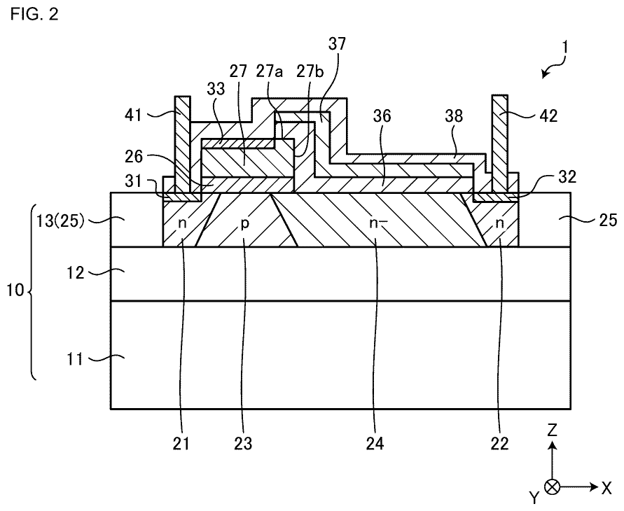

FIG. 1 is a plan view of a semiconductor device according to the first embodiment. FIG. 2 is a cross-sectional view taken along line II-II in FIG. 1. In FIG. 1, to make the drawing easier to understand, a silicon nitride film 38 is illustrated in dashed double-dotted lines. In addition, to avoid unnecessary complexity in the subsequent drawings, sidewalls of a gate electrode 27 described later are not illustrated.

As illustrated in FIGS. 1 and 2, the semiconductor device 1 includes an SOI substrate 10 (a semiconductor substrate) and a source region 21, a drain region 22, a body region 23, and a drift region 24 formed on the upper surface side of the SOI substrate 10. The semiconductor device 1 also includes a gate insulating film 26, the gate electrode 27, silicide portions 31, 32, and 33, and insulating films. Note that the source region 21, the drain region 22, the body region 23, and the drift region 24 are respectively provided under the silicide portion 31, the silicide portion 32, a combination of the silicide portion 33 and the gate electrode 27, and a combination of an insulating film 36 and an SiON film 37 so as to overlap them. Hence, these regions are not illustrated in FIG. 1.

As illustrated in FIG. 2, the SOI (silicon on insulator) substrate 10 includes a support substrate 11, a buried oxide layer 12, and a surface silicon layer 13. In the SOI substrate 10, the support substrate 11, the buried oxide layer 12, the surface silicon layer 13 are laminated in this order. In other words, the buried oxide layer 12 is located between the support substrate 11 and the surface silicon layer 13 in the Z direction. The support substrate 11 is a silicon substrate having a thickness of, for example, approximately 725 μm. The thickness of the buried oxide layer 12 is, for example, approximately 400 nm. The thickness of the surface silicon layer 13 is, for example, approximately 4 nm or more and 140 nm or less (i.e., from 4 nm to 140 nm), preferably 70 nm or less. In the case in which the thickness of the surface silicon layer 13 is 70 nm or less, the SOI substrate 10 is formed as a fully depleted SOI (FDSOI), reducing the influence of the capacitance of the substrate and improving characteristics.

In the following description, a direction parallel to the surface of the SOI substrate 10 (the surface silicon layer 13) is defined as the X direction. The Y direction is the direction parallel to the surface of the SOI substrate 10 (the surface silicon layer 13) and orthogonal to the X direction. The Z direction is the direction perpendicular to the surface of the SOI substrate 10 (the surface silicon layer 13) and orthogonal to the X direction and the Y direction. Plan views are views showing the arrangement when viewed in the direction (the Z direction) perpendicular to the surface of the SOI substrate 10.

The surface silicon layer 13 includes the source region 21, the drain region 22, the body region 23, and the drift region 24. An insulating region 25 is provided so as to surround the source region 21, the drain region 22, the body region 23, and the drift region 24. The insulating region 25 is formed of, for example, silicon oxide.

The source region 21 and the drain region 22 are located on the surface side of the surface silicon layer 13 (the main surface side of the semiconductor substrate) and are spaced from each other in the X direction. The source region 21 and the drain region 22 are both heavily doped n-type semiconductors. The body region 23 is located between the source region 21 and the drain region 22 in the X direction. The drift region 24 is located between the body region 23 and the drain region 22 in the X direction. Hence, the source region 21, the body region 23, the drift region 24, and the drain region 22 are arranged in this order in the X direction on the surface side of the surface silicon layer 13 (the main surface side of the semiconductor substrate).

The body region 23 is a region that overlaps the gate electrode 27 and in which a channel region is formed. The body region 23 is a p-type semiconductor formed in the surface silicon layer 13 by using boron (B) as a dopant.

The drift region 24 is a lightly doped n-type semiconductor with a lower concentration than the drain region 22. The drift region 24 in the semiconductor device 1 prevents electric field concentration between the gate and the drain. This configuration in the semiconductor device 1, for example, when a specified gate voltage is applied to the gate electrode 27, prevents accelerated electrons from damaging the gate insulating film 26.

The gate insulating film 26 and the gate electrode 27 are laminated over the body region 23. In other words, the gate insulating film 26 is located between the body region 23 and the gate electrode 27 in the Z direction. As illustrated in FIG. 2, the gate insulating film 26 and the gate electrode 27 cover not only the body region 23 but also part of the source region 21 adjacent to the body region 23 and part of the drift region 24 adjacent to the body region 23.

The gate insulating film 26 is, for example, silicon oxide formed by thermal oxidation. The thickness of the gate insulating film 26 is, for example, approximately 5.5 nm or more and 7.5 nm or less (i.e., from 5.5 nm to 7.5 nm). However, the thickness is not limited to this range. For example, the thickness of the gate insulating film 26 for high-voltage applications may be, for example, approximately 10 nm.

The gate electrode 27 is formed of, for example, polysilicon. The thickness of the gate electrode 27 is, for example, approximately 100 nm or more and 160 nm or less (i.e., from 100 nm to 160 nm). The gate electrode 27 may be amorphous or non-amorphous. The gate electrode 27 may contain impurities added by ion implantation. In this case, the concentration of impurities is, for example, approximately 10²⁰ cm⁻³.

The silicide portions 31, 32, and 33 are formed on the surfaces of the source region 21, the drain region 22 and the gate electrode 27, respectively. The silicide portions 31, 32, and 33 may be self-aligned silicide portions (salicides). The silicide portion 31 reduces the coupling resistance between the source region 21 and contacts 41. Similarly, the silicide portion 32 reduces the coupling resistance between the drain region 22 and contacts 42. The silicide portion 33 reduces the coupling resistance between the gate electrode 27 and contacts 43 (not illustrated in FIG. 2).

As illustrated in FIG. 1, the silicide portion 31 (the source region 21), the silicide portion 32 (the drain region 22), the silicide portion 33, and the gate electrode 27 (the body region 23) have rectangular shapes extending in the Y direction. The insulating film 36 and the SiON film 37 (the drift region 24) have quadrangular shapes that are shorter in the Y direction and longer in the X direction than the silicide portions 31, 32, and 33 and the like.

The semiconductor device 1 includes the insulating film 36, the silicon oxynitride film 37, and the silicon nitride film 38, as a plurality of insulating films. In the following description, the silicon oxynitride film 37 is referred to as the SiON film 37. The silicon nitride film 38 is referred to as the SiN film 38.

The insulating film 36 is provided on the drift region 24. The insulating film 36 also covers an upper surface 27a which is a portion of the upper surface of the gate electrode 27 on the drain region 22 side and a side surface 27b of the gate electrode 27 on the drain region 22. The insulating film 36 is not provided on a portion of the upper surface of the gate electrode 27 on the source region 21 side. The insulating film 36 is formed of, for example, silicon oxide (SiO₂).

In the example illustrated in FIG. 2, the insulating film 36 is in direct contact with the drift region 24 and the upper surface 27a and side surface 27b of the gate electrode 27. However, sidewalls (not illustrated) are formed around the gate electrode 27 in some cases. In such a case, the insulating film 36 is in direct contact with the drift region 24 and the upper surface 27a of the gate electrode 27 and is adjacent to the side surface 27b of the gate electrode 27 with a sidewall interposed therebetween.

Since the insulating film 36 is provided on the drift region 24 and the upper surface 27a of the gate electrode 27, it is possible to prevent a silicide portion from being formed at least in the drift region 24. In other words, the silicide portions 31, 32, and 33 are formed in the regions where the insulating film 36 is not provided on the source region 21, the gate electrode 27 (the body region 23), the drift region 24, and the drain region 22.

The SiON film 37 is provided on the insulating film 36. The SiON film 37 has a plan-view shape equivalent to that of the insulating film 36. Specifically, the SiON film 37 is provided over the drift region 24 and covers the upper surface 27a and the side surface 27b of the gate electrode 27 on the drain region 22 side. The insulating film 36 and the SiON film 37 are not provided over the portion of the upper surface of the gate electrode 27 on the source region 21 side. The insulating film 36 and the SiON film 37 are provided over the entire surface of the drift region 24.

The thickness of the SiON film 37 is approximately 5 nm or more and 50 nm or less (i.e., from 5 nm to 50 nm) and is, for example, 10 nm. The SiON film 37 preferably has such a thickness that the insulating film 36 (SiO₂) and the SiN film 38 are not in contact with each other. Due to the SiON film 37, no interface between the insulating film 36 (SiO₂) and the SiN film 38 is formed. Note that FIG. 2 shows the interfaces between side surfaces of the insulating film 36 and the SiN film 38. However, the thicknesses of the insulating film 36, the SiON film 37, and the SiN film 38 are exaggerated in FIG. 2 to make the drawing easier to understand. In practice, the surface areas of the interfaces between the side surfaces of the insulating film 36 and the SiN film 38 are so small that they can be ignored.

The SiN film 38 covers the entire part of the semiconductor device 1. The SiN film 38 continuously extends across the regions overlapping the source region 21, the body region 23, the drift region 24, and the drain region 22. The SiN film 38 is formed to exert stress on the body region 23. In the case in which the thickness of the SiON film 37 provided under the SiN film 38 is thicker than, for example, 50 nm, there is a possibility that stress cannot be favorably exerted by the SiN film 38.

More specifically, the SiN film 38 is provided over the insulating film 36 and the SiON film 37 in the regions overlapping the drift region 24 and the upper surface 27a of the gate electrode 27. In the Z direction, the SiON film 37 is located between the insulating film 36 and the SiN film 38. In the regions where the insulating film 36 and the SiON film 37 are not provided, the SiN film 38 is provided on the silicide portions 31, 32, and 33 on the source region 21, the gate electrode 27 (the body region 23), and the drain region 22, respectively.

Specifically, on the portion of the upper surface of the gate electrode 27 on the source region 21 side, the silicide portion 33 and the SiN film 38 are laminated in this order. Over the upper surface 27a of the gate electrode 27 on the drain region 22 side, the insulating film 36, the SiON film 37, and the SiN film 38 are laminated in this order. Over the drift region 24, the insulating film 36, the SiON film 37, and the SiN film 38 are laminated in this order.

In the configuration described above, since the semiconductor device 1 includes the SiON film 37, it is possible to prevent the insulating film 36 (silicon oxide) and the SiN film 38 from being in contact with each other in the lamination structure. In other words, no interface between the insulating film 36 and the SiN film 38 is formed. Thus, when a specified gate voltage is applied to the gate electrode 27, this configuration prevents electrons accelerated at the p-n junction interface from being trapped at the interface between the insulating film 36 and the SiN film 38. In other words, since the present embodiment prevents the transient response that would occur when electrons are trapped, it is possible to prevent degradation in the transistor characteristics, compared with configurations without the SiON film 37.

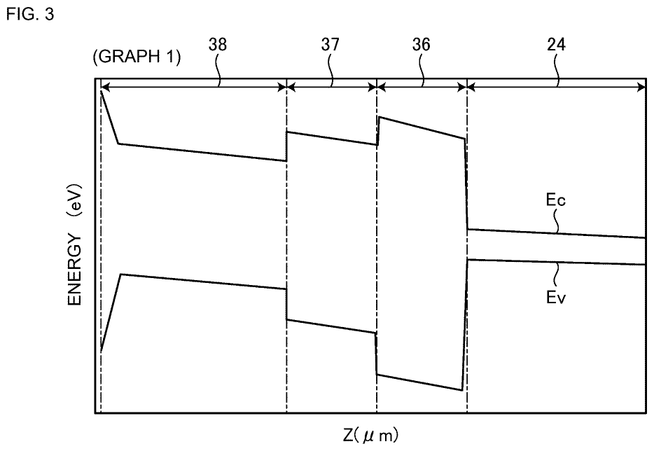

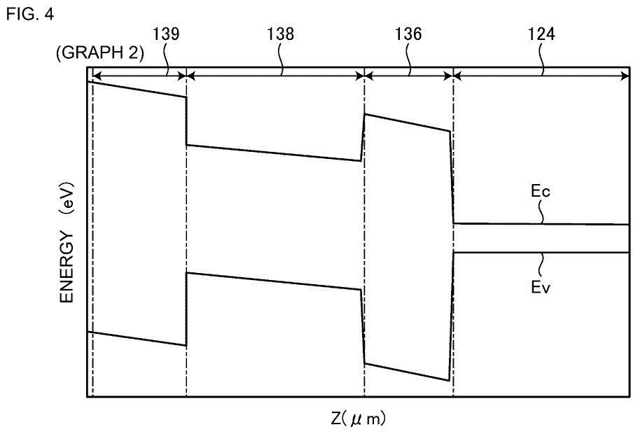

FIG. 3 is an explanatory diagram for explaining the energy band of the lamination structure including the drain region, the insulating film, the SiON film, and the SiN film in the semiconductor device according to the first embodiment. FIG. 4 is an explanatory diagram for explaining the energy band of a lamination structure including a drain region, an insulating film, an SiN film, and an SiO₂ film in a semiconductor device according to a comparative example.

The semiconductor device according to the comparative example illustrated in FIG. 4 is different from the semiconductor device 1 according to the first embodiment in that the former does not include the SiON film 37. Specifically, in the comparative example, the insulating film 136 and the SiN film 138 are laminated in this order over the drift region 124. The insulating films 36 and 136 of the first embodiment and the comparative example are both formed of silicon oxide (SiO₂). In the comparative example, the SiO₂ film 139 is additionally provided on the SiN film 138. However, the SiO₂ film 139 is not essential.

The vertical axis of each of the graphs illustrated in FIGS. 3 and 4 represents the band energy in a state in which an electric field is applied to the drain, and the horizontal axis represents the position in the Z direction in and over the drift region 24 or 124. In the graphs illustrated in FIGS. 3 and 4, Ev indicates the energy of the valence band, and Ec indicates the energy of the conduction band. The band gap Eg is expressed as Ec-Ev.

As illustrated in FIG. 4, in the semiconductor device according to the comparative example, the band gap of the SiN film 138 is smaller than the band gap of the insulating film 136 (SiO₂). Hence, it is considered that when a gate voltage is applied, electrons accelerated at the p-n junction interface overcome the barrier between the insulating film 136 and the drift region 124 and are trapped at the interface between the insulating film 136 and the SiN film 138. Since it takes a certain time for the trapped electrons to return to the drift region 124, there is a possibility that the occurrence of a transient response affects the transistor characteristics.

As illustrated in FIG. 3, in the semiconductor device 1 according to the first embodiment, the band gap of the SiON film 37 is larger than the band gap of the SiN film 38. In other words, the band gap difference between the insulating film 36 and the SiON film 37 is smaller than the band gap difference between the insulating film 136 and the SiN film 138 in the comparative example (FIG. 4). With this configuration, since no interface between the insulating film 136 and the SiN film 138 is formed in the semiconductor device 1 according to the first embodiment, it is possible to prevent electrons from being trapped at the interface between the insulating film 36 and the SiON film 37. This prevents the occurrence of a transient response that affects the transistor characteristics.

Note that the plan-view shapes of each electrode and each insulating film illustrated in FIG. 1 are mere examples, and the present disclosure is not limited to these. For example, the plan-view shapes of the source region 21, the drain region 22, the body region 23, and the drift region 24 are not limited to quadrangular shapes and may be other shapes such as polygonal, circular, and elliptical shapes. The plan-view shapes of the silicide portions 31, 32, and 33, the gate electrode 27, and the like may also be changed as appropriate depending on the source region 21, the drain region 22, the body region 23, and the drift region 24. The thicknesses of each electrode and each insulating film illustrated in FIG. 2 are exaggerated to make the drawing easy to understand. The thicknesses of each electrode and each insulating film described above are mere examples and may be changed as appropriate.

Next, as an example of a method of manufacturing the semiconductor device 1, an example using the SOI substrate 10 will be described. The insulating region 25 is formed in the surface silicon layer 13 of the SOI substrate 10 by, for example, etching and a masking technique. For example, a mask layer using photoresist is formed on the SOI substrate 10, and then anisotropic etching (for example, RIE: reactive ion etching) is performed on it. Thereafter, for example, a dielectric material such as silicon oxide is introduced to form the insulating region 25.

After the insulating region 25 is formed, a first well which serves as the body region 23 is formed. The first well is formed by using, for example, boron (B) as a dopant.

Next, the gate insulating film 26 and the gate electrode 27 are formed over the body region 23. The gate insulating film 26, which is a silicon oxide film formed by, for example, thermal oxidation, is formed on the upper surface of the body region 23. The gate electrode 27 is formed on the gate insulating film 26 by using, for example, polysilicon. The gate electrode 27 can be formed by, for example, chemical vapor deposition (CVD) to achieve lower resistance. The thickness of the gate electrode 27 and the concentration of the impurities in the gate electrode 27 are as mentioned above.

Next, after the sidewalls (not illustrated) of the gate electrode 27 are formed, the drift region 24 is formed in the surface silicon layer 13. The drift region 24 is an n-type semiconductor, and the dopant concentration of which is, for example, approximately 10¹⁵ cm⁻³ or more and 10¹⁸ cm⁻³ or less (i.e., from 10¹⁵ cm⁻³ to 10¹⁸ cm⁻³).

Next, the source region 21 and the drain region 22 are formed in the surface silicon layer 13. The source region 21 and the drain region 22 are heavily doped n-type semiconductors.

Next, the insulating film 36 (SiO₂) and the SiON film 37 are formed. The insulating film 36 (SiO₂) and the SiON film 37 are formed in this order by CVD using the same mask. Thereafter, openings are formed in the regions of the insulating film 36 (SiO₂) and the SiON film 37 where the silicide portions 31, 32, and 33 are to be formed. The thickness of the insulating film 36 (SiO₂) is, for example, approximately 40 nm or more and 100 nm or less (i.e., from 40 nm to 100 nm). The thickness of the SiON film 37 is, for example, approximately 5 nm or more and 50 nm or less (i.e., from 5 nm to 50 nm).

Then, after the silicide portions 31, 32, and 33 are formed, the SiN film 38 is formed on the entire surface, thereby manufacturing the semiconductor device 1. Note that the manufacturing method described above is a mere example and may be changed as appropriate. For example, the insulating film 36 (SiO₂) and the SiON film 37 may be formed to have different plan-view shapes by using different masks.

### Second Embodiment

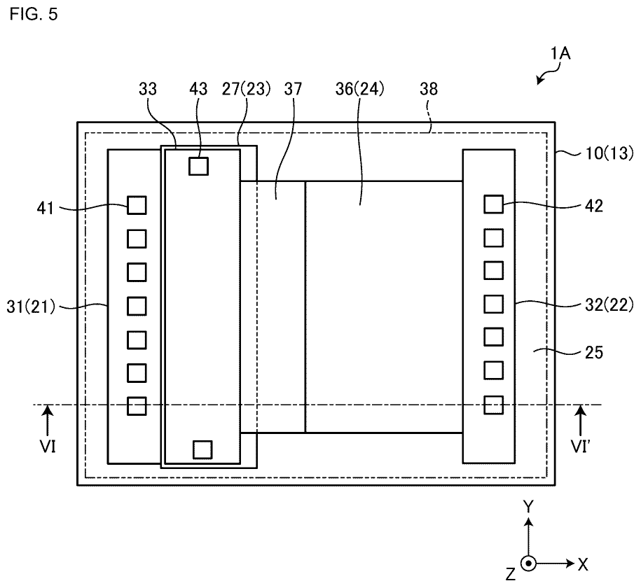

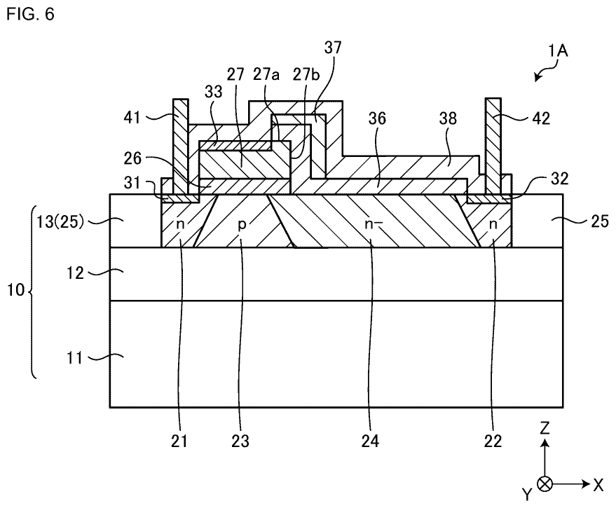

FIG. 5 is a plan view of a semiconductor device according to the second embodiment. FIG. 6 is a cross-sectional view taken along line VI-VI in FIG. 5. As illustrated in FIGS. 5 and 6, the semiconductor device 1A according to the second embodiment is different from the above-mentioned first embodiment in that an SiON film 37 is not provided in a region overlapping a drift region 24 in the semiconductor device 1A.

The SiON film 37 has a different plan-view shape and a different area from those of the insulating film 36. Specifically, the insulating film 36 is provided so as to cover the drift region 24 and the upper surface 27a and the side surface 27b of the gate electrode 27 on the drain region 22 side. The SiON film 37 is provided on the insulating film 36 so as to cover the upper surface 27a and the side surface 27b of the gate electrode 27 on the drain region 22 side. The SiON film 37 is not provided over a portion of the drift region 24 on the drain region 22 side.

Over a region of the drift region 24 close to the boundary between the body region 23 and the drift region 24, the insulating film 36, the SiON film 37, and the SiN film 38 are laminated in this order. Over the portion of the drift region 24 on the drain region 22 side, the SiON film 37 is not provided, and the insulating film 36 and the SiN film 38 are laminated in this order.

In the present embodiment, the SiON film 37 is provided over a region overlapping the boundary between the body region 23 and the drift region 24. In other words, no interface between the insulating film 36 and the SiN film 38 is formed at least over a region overlapping the p-n junction interface of the surface silicon layer 13. This configuration effectively prevents electrons generated at the p-n junction interface from being trapped at the interface between the insulating film 36 and the SiON film 37. In addition, since the SiN film 38 is laminated on the insulating film 36 over most of the drift region 24, the second embodiment provides the effect of the SiN film 38 more favorably and exerts stress more efficiently than the first embodiment.

### Third Embodiment

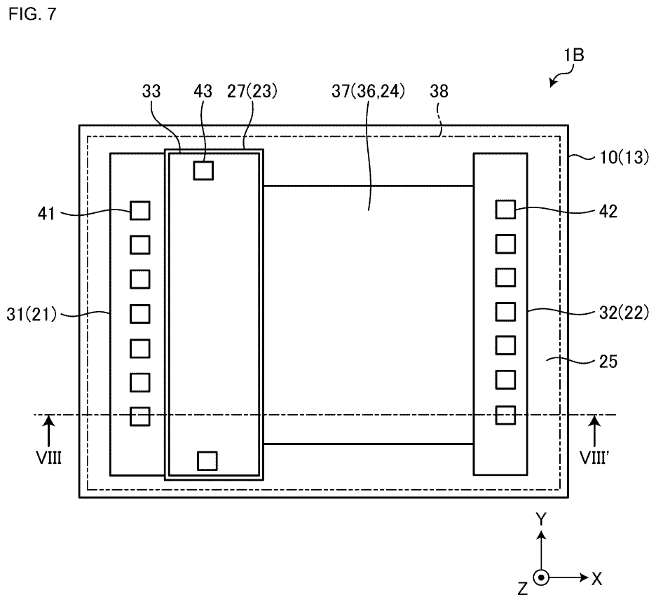

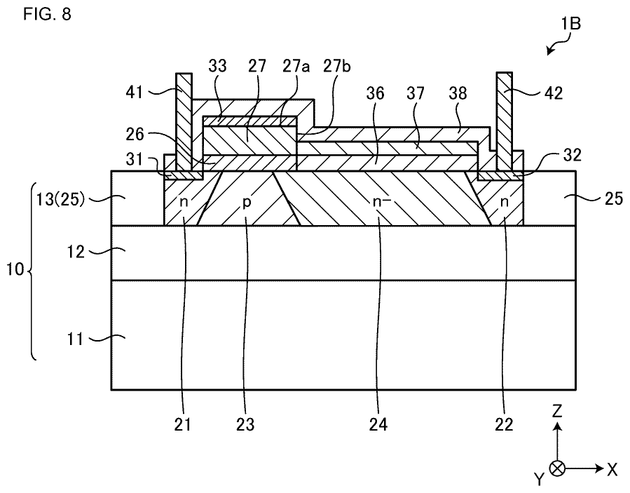

FIG. 7 is a plan view of a semiconductor device according to the third embodiment. FIG. 8 is a cross-sectional view taken along line VIII-VIII in FIG. 7. As illustrated in FIGS. 7 and 8, the semiconductor device 1B according to the third embodiment is different from the above-mentioned embodiments in that an insulating film 36 and an SiON film 37 cover the drift region 24 and are not provided over the gate electrode 27.

The insulating film 36 and the SiON film 37 cover approximately the entire surface of the drift region 24. Over the drift region 24, the insulating film 36, the SiON film 37, and an SiN film 38 are laminated in this order.

Unlike the above-mentioned embodiments, the insulating film 36 and the SiON film 37 are not provided over the upper surface 27a of the gate electrode 27 on the drain region 22 side. A silicide portion 33 is formed on the entire upper surface of the gate electrode 27. The SiN film 38 is provided over the gate electrode 27 (the silicide portion 33).

In the present embodiment, since the area of the silicide portion 33 can be large, it is possible to reduce the resistance of the gate electrode 27. In addition, the insulating film 36 and the SiON film 37 are not provided and the SiN film 38 is provided over the gate electrode 27. This configuration, having no interface between the insulating film 36 and the SiN film 38 over the gate electrode 27, prevents electrons from being trapped.

Although the description in the above-mentioned embodiments is based on the configurations in which the SiON film 37 is located between the insulating film 36 and the SiN film 38, the material of the film 37 is not limited to SiON and may be a material having a band gap larger than that of the SiN film 38. Although the above description is based on examples using the SOI substrate 10 for the semiconductor device 1, the present disclosure is not limited to these. A bulk semiconductor substrate may also be used.

The embodiments described above are to facilitate understanding of the present disclosure and are not intended to limit the interpretation of the present disclosure. The present disclosure can be changed or improved without departing from the spirit thereof, and the present disclosure also includes equivalents thereof.

What is claimed is:

1. A semiconductor device comprising:
a semiconductor substrate;
a source region and a drain region on an upper surface side of the semiconductor substrate and spaced from each other;
a body region between the source region and the drain region;
a drift region between the body region and the drain region;
a gate insulating film on the body region;
a gate electrode on the gate insulating film;
an insulating film on the drift region;
a silicon oxynitride film on the insulating film; and
a silicon nitride film on the silicon oxynitride film.

2. The semiconductor device according to claim 1, wherein
the insulating film and the silicon oxynitride film cover the drift region, a portion of an upper surface of the gate electrode on the drain region side, and a side surface of the gate electrode on the drain region side, and
the insulating film and the silicon oxynitride film are not laminated over a portion of the upper surface of the gate electrode on the source region side.

3. The semiconductor device according to claim 1, wherein
the insulating film and the silicon oxynitride film cover an entire surface of the drift region.

4. The semiconductor device according to claim 1, wherein
the insulating film, the silicon oxynitride film, and the silicon nitride film are laminated in this order over the drift region,
the insulating film, the silicon oxynitride film, and the silicon nitride film are laminated in this order over a portion of an upper surface of the gate electrode on the drain region side, and
the silicon nitride film is on a portion of the upper surface of the gate electrode on the source region side.

5. The semiconductor device according to claim 1, wherein
the insulating film covers the drift region, a portion of an upper surface of the gate electrode on the drain region side, and a side surface of the gate electrode on the drain region side,
the silicon oxynitride film covers the portion of the upper surface of the gate electrode on the drain region side and the side surface of the gate electrode on the drain region side, and
the silicon oxynitride film is not provided, and the insulating film and the silicon nitride film are laminated, over a portion of the drift region on the drain region side.

6. The semiconductor device according to claim 1, wherein
the insulating film and the silicon oxynitride film cover the drift region, and
the insulating film and the silicon oxynitride film are not provided, and the silicon nitride film is provided, over the gate electrode.

7. The semiconductor device according to claim 1, wherein
the insulating film includes silicon oxide.

8. The semiconductor device according to claim 1, wherein
the semiconductor substrate is an SOI substrate.

9. The semiconductor device according to claim 8, wherein
the SOI substrate is a fully depleted SOI substrate.

10. The semiconductor device according to claim 2, wherein
the insulating film and the silicon oxynitride film cover an entire surface of the drift region.

11. The semiconductor device according to claim 2, wherein
the insulating film, the silicon oxynitride film, and the silicon nitride film are laminated in this order over the drift region,
the insulating film, the silicon oxynitride film, and the silicon nitride film are laminated in this order over a portion of an upper surface of the gate electrode on the drain region side, and
the silicon nitride film is on a portion of the upper surface of the gate electrode on the source region side.

12. The semiconductor device according to claim 3, wherein
the insulating film, the silicon oxynitride film, and the silicon nitride film are laminated in this order over the drift region,
the insulating film, the silicon oxynitride film, and the silicon nitride film are laminated in this order over a portion of an upper surface of the gate electrode on the drain region side, and
the silicon nitride film is on a portion of the upper surface of the gate electrode on the source region side.

13. The semiconductor device according to claim 2, wherein
the insulating film includes silicon oxide.

14. The semiconductor device according to claim 3, wherein
the insulating film includes silicon oxide.

15. The semiconductor device according to claim 4, wherein
the insulating film includes silicon oxide.

16. The semiconductor device according to claim 5, wherein
the insulating film includes silicon oxide.

17. The semiconductor device according to claim 2, wherein
the semiconductor substrate is an SOI substrate.

18. The semiconductor device according to claim 3, wherein
the semiconductor substrate is an SOI substrate.

19. The semiconductor device according to claim 4, wherein
the semiconductor substrate is an SOI substrate.

20. The semiconductor device according to claim 5, wherein
the semiconductor substrate is an SOI substrate.
